(19) United States
(12) Patent Application Publication
(10) Pub. No.: US 2026/0162918 A1
(43) Pub. Date: Jun. 11, 2026

(54) THREE-PHASE CIRCUIT BREAKER BUSBAR

(71) Applicant: Vertiv Corporation, Westerville, OH (US)

(72) Inventors: Zachary Ray Wilcoxen, Delaware, OH (US); Patrick G. Esber, Delaware, OH (US)

(21) Appl. No.: 19/410,441

(22) Filed: Dec. 5, 2025

Related U.S. Application Data
(60) Provisional application No. 63/728,877, filed on Dec. 6, 2024.

(51) Int. Cl. H01H 33/02; H01R 25/16; H05K 7/14

(52) U.S. Cl. CPC H01H 33/022; H01R 25/161; H05K 7/1492

(57) ABSTRACT

A busbar for a three-phase circuit breaker includes a first connection side including a first bend, a second bend, and a third bend, the first connection side extending in a first direction, a second connection side including a fourth bend, the second connection side extending in the first direction, and a middle portion extending in a second direction, perpendicular to the first direction, between the first connection side and the second connection side. The first connection side includes at least first and second layers.

### CROSS-REFERENCE TO RELATED APPLICATIONS

This application claims the benefit of U.S. Provisional Application No. 63/728,877, filed on Dec. 6, 2024. The entire disclosure of the application referenced above is incorporated herein by reference.

### FIELD

The present disclosure relates to busbars for three-phase circuit breakers.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Various systems use one or more power distribution units (PDUs) to receive output power (e.g., from a power transformer cabinet) and distribute the received power via a plurality of output distribution power cables (e.g., to a plurality of different components, power output panelboards, etc.). For example, in a data center or other environment with a plurality of servers, server racks, and/or other components, PDUs may be mounted in server racks and distribute power to individual servers. In some examples, PDUs may including built-in monitoring and controls and require printed circuit boards, power supplies, and other electronic modules. The lugs of these input cables and the busbar they connect to are live parts with hazardous voltage on them. In some examples, PDUs are configured to operate in three-phase power systems.

### SUMMARY

A busbar for a three-phase circuit breaker includes a first connection side including a first bend, a second bend, and a third bend, the first connection side extending in a first direction, a second connection side including a fourth bend, the second connection side extending in the first direction, and a middle portion extending in a second direction, perpendicular to the first direction, between the first connection side and the second connection side. The first connection side includes at least first and second layers.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example busbar according to the principles of the present disclosure.

FIG. 2 shows a plurality of the busbars of FIG. 1 in a three-phase circuit breaker arrangement according to the principles of the present disclosure.

In the drawings, reference numbers may be reused to identify similar and/or identical elements.

### DETAILED DESCRIPTION

Reference will now be made in detail to example embodiments which are illustrated in the accompanying drawings, wherein like reference numerals refer to like elements throughout. In this regard, the example embodiments may have different forms and may not be construed as being limited to the descriptions set forth herein.

It will be understood that the terms “include,” “including”, “comprise, and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “approximately” may correspond to “within +/−5% of.”

It will be further understood that, although the terms “first,” “second,” “third,” etc., may be used herein to describe various elements, components, regions, layers and/or sections, these elements, components, regions, layers and/or sections may not be limited by these terms. These terms are only used to distinguish one element, component, region, layer or section from another element, component, region, layer or section.

As used herein, the term “and/or” includes any and all combinations of one or more of the associated listed items. Expressions such as “at least one of,” when preceding a list of elements, modify the entire list of elements and do not modify the individual elements of the list.

Various terms are used to refer to particular system components. Different companies may refer to a component by different names. As such, this document does not intend to distinguish between components that differ in name but not function.

Matters of these example embodiments that are obvious to those of ordinary skill in the technical field to which these example embodiments pertain may not be described herein in detail.

Three-phase circuit breakers are configured to protect electrical circuits in three-phase power systems by interrupting flow of electric current in various conditions (e.g., in response to detecting/being triggered by an overload, a short circuit, etc.). In some examples, circuit breakers (including three-phase circuit breakers) and/or other electrical connections may include on or more busbars configured and arranged to carry electrical current (e.g., one busbar for each phase).

Three-phase circuit breakers may be used in applications that push the limits of thermal tolerances. In some examples, breaker poles of a circuit breaker (e.g., where conductors attach to the breaker poles) may be susceptible to thermal failure. There are a variety of ways to connect conductors to respective breaker poles. In some examples, busbars are used to connect the conductors to the breaker poles. In some examples, when there are difficulties meeting thermal limits, busbars can be increased in size to facilitate distribution of heat away from hot spots (e.g., a breaker connection point) on the breaker pole. As busbar size increases, meeting clearance requirements between phases of the circuit breaker can be difficult. For example, a three-phase circuit breaker may include one or more phase barriers that provide insulation between adjacent phases. However, if one or more of the busbars are sufficiently large and extends above or behind the phase barriers, clearance requirements are no longer met.

In some examples, one or more of the busbars (e.g., a B phase busbar) may have a different design or configuration relative to other busbars (e.g., A and C busbars) to facilitate meeting clearance requirements. As one example, the B phase busbar may be offset set from and/or be bent at a different angle than the A and C phase busbars. However, having different designs/configurations for different busbars of the same breaker increases manufacturing cost and complexity.

Busbar designs according to the present disclosure can be used for all three busbar phases of a three-phase circuit breaker while maintaining clearance requirements. Further, busbars as described herein have increased material thickness at the breaker connection point (i.e., a hot spot) to help alleviate thermal problems at this and other locations.

Accordingly, the busbar according to the present disclosure is configured to maximize performance of three-phase circuit breakers to deliver higher power density while also ensuring desired operating temperatures and electrical clearance requirements. The ability to use the same, common design/configuration for all three busbar phases allows for increased component volumes, which reduces cost and mitigates part shortage risks. Further, the use of the common busbar design allows products to be manufactured more quickly and at a lower cost.

Busbar designs as described herein also increase ampacity. Ampacity is the measure (e.g., in amps) of the ability of a conductor to conduct current without exceeding temperature ratings. Ampacity is directly proportional to a cross-sectional area of the conductor. For example, for a rectangular busbar as described herein, the cross-sectional area is thickness * width. Accordingly, doubling the width of the busbar also doubles the cross-sectional area and increases ampacity.

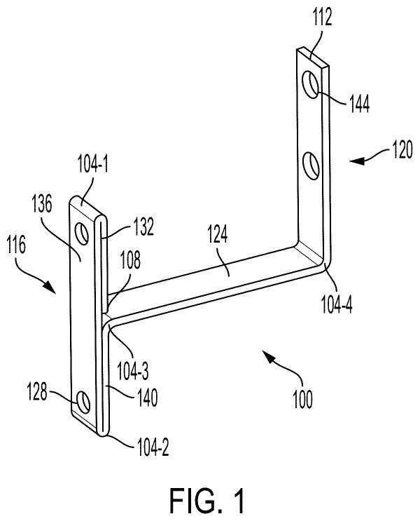

FIG. 1 shows an example busbar 100 according to the principles of the present disclosure. Although described herein in the context of a three-phase circuit breaker, the busbar 100 may be implemented in other types of electrical power distribution systems and devices. In this example, the busbar 100 is generally flat and rectangular (i.e., has a generally rectangular cross-section) and is comprised of copper. In other examples, the busbar 100 may include other conductive materials.

The busbar 100 includes a plurality of bends 104-1 (e.g., a first bend), 104-2 (e.g., a second bend), 104-3 (e.g., a third bend), and 104-4 (e.g., a fourth bend), referred to collectively as bends 104. Accordingly, as shown, the busbar is comprised of a single conductive member or bar (e.g., a generally linear, flat, rectangular bar) having a first end 108, a second end 112, and the plurality of bends 104.

The bends 104 result in a configuration or shape of the busbar 100 having a first connection end or side 116 and a second connection end or side 120. The first connection side 116 may correspond to a breaker connection side of the busbar 100 (i.e., a side of the busbar 100 configured to connect/electrically couple to a three-phase circuit breaker). Conversely, the second connection side 120 may correspond to a conductor connection side of the busbar 100 (i.e., a side of the busbar 100 configured to connect/electrically couple to a conductor wire supplying electrical power to an electrical device).

In this example, the first connection side 116 and the second connection side 120 are generally vertical and are coupled/joined by a generally horizontal middle portion 124. In other examples (e.g., with the busbar 100 in a different orientation relative to circuit breaker, electrical device, etc.), the first connection side 116, the second connection side 120, and the middle portion 124 may have other orientations. For example, the first connection side 116 and the second connection side 120 may be generally horizontal while the middle portion 124 may be generally vertical. In another example, the first connection side 116, the second connection side 120, and the middle portion 124 may each be generally horizontal (e.g., with the busbar rotated 90 degrees about an axis defined by the middle portion 124). In some examples, lengths of the first connection side 116, the second connection side 120, and/or the middle portion 124 are approximately equal. In other examples, lengths of the first connection side 116, the second connection side 120, and/or the middle portion 124 are different.

The first (breaker) connection side 116 includes the first bend 104-1, the second bend 104-2, and the third bend 104-3 and one or more breaker connection points 128 configured to couple the busbar 100 to the circuit breaker. For example, the breaker connection point 128 may include a hole or opening configured to receive a bolt, lug, stud, post, etc. (not shown) or other coupling mechanism.

The first, second, and third bends 104-1, 104-2, 104-3 are configured such that the first connection side 116 is comprised of multiple (two) folds or layers. In other words, the busbar 100 is folded/bent such that a material thickness of the first connection side 108 is doubled relative to the second connection side 120 and the middle portion 124. Doubling the thickness (and, accordingly, the cross-sectional area) of the first connection side 108 doubles the ampacity of the first connection side 108 while also increasing thermal capacity at the breaker connection point 128 (which corresponds to a hot spot of the busbar 100), thereby improving thermal performance. In other words, the doubled thickness and additional layers increases the amount of material comprising the first connection side 116, allowing the first connection side 116 to function as a heat sink and increasing the amount of heat distributed from the breaker connection point/pole 128. In some examples, the first connection side 116 may be comprised of more than two folds or layers.

As shown, the first bend 104-1 and the second bend 104-2 are approximately 180 degree bends. As one example, the busbar 100 extends generally upward/vertically from the first end 108 toward the first bend 104-1 to define a first layer 132. The first bend 104-1 bends and causes the busbar 100 to extend generally downward from the first bend 104-1 toward the second bend 104-2 to define a second layer 136. The second bend 104-2 bends and causes the busbar 100 to extend generally upward from the second bend 104-2 back toward the first end 108 and the third bend 104-3 to define a third layer 140. Although referred to as the first layer 132 and the third layer 140, the first and third layers 132, 134 may be coplanar as shown and correspond to a same layer of the first connection side 116.

The third bend 104-3 and the fourth bend 104-4 are approximately 90 degree bends. As shown, the third bend 104-3 (and the first end 108) is located at/aligned with approximately a midpoint of the first connection side 116. For example, the midpoint of the first connection side 116 may be located between the first end 108 and the third bend 104-3. In other words, the arrangement of the first connection side 116 and the middle portion 124 is generally symmetrical (e.g., in a vertical direction about an axis defined by the middle portion 124). In this manner, the busbar 100 can be inverted (i.e., inverted 180 degrees about the axis defined by the middle portion 124, which may be referred to as an inverted configuration) and still connect to a three-phase circuit breaker (e.g., using the same or another one of the breaker connection points 128). In some examples, respective distances of the breaker connection points 128 from the midpoint of the first connection side 116 are approximately the same.

The third bend 104-3 bends and causes the busbar 100 to extend generally horizontally from the first end 108 and the third bend 104-3 (e.g., and the midpoint of the first connection side 116) toward the fourth bend 104-4 to define the middle portion 124. The fourth bend 104-4 bends and causes the busbar 100 to extend generally upward from the third bend 104-3 toward the second end 112 to define the second connection side 120. The second connection side 120 may include one or more conductor connection points 144 for connecting the second connection side 120 to one or more conductors.

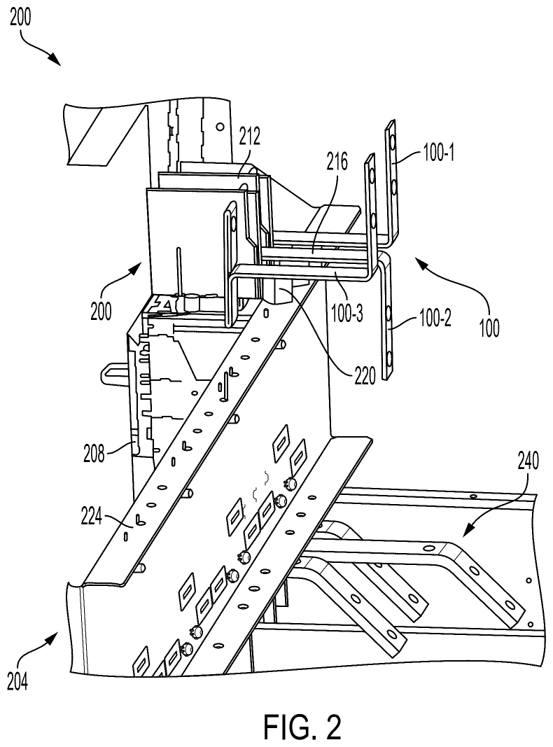

Referring now to FIG. 2 (and with continued reference to FIG. 1), a plurality (e.g., three) of the busbars (e.g., busbars 100-1, 100-2, and 100-3, referred to collectively as the busbars 100) are shown in a three-phase circuit breaker arrangement (e.g., coupled to a three-phase circuit breaker 200). As shown, the busbars 100 are located in a server rack or system 204, such as a server rack 204 with a PDU 208 configured to receive electrical power via the busbars 100 and the circuit breaker 200 and distribute the power to servers and other components within the server rack 204. In some examples, as shown, the circuit breaker 200 includes one or more phase barriers 212 that provide insulation between adjacent phases (and, therefore, between adjacent busbars).

One or more of the busbars 100 can be inverted (e.g., inverted 180 degrees) or rotated relative to others of the busbars 100 to meet spacing or clearance requirements (e.g., clearance requirements associated with conductors connected to the second connection sides 120). More specifically, the same busbar configuration (e.g., the busbar 100 as described in detail in FIG. 1) can be used for all three of the busbars 100-1, 100-2, and 100-3 (i.e., all three of the phases of the circuit breaker 200). In this example, the busbar 100-2 (e.g., a middle busbar) is inverted relative to the busbars 100-1 and 100-3. For example, in the shown configuration, the second connection sides 120 of the busbars 100-1 and 100-3 extend vertically upward while the second connection side 120 of the busbar 100-2 extends vertically downward.

In some examples, portions of one or more of the busbars 100 may be insulated. For example, as shown, the busbar 100-2 includes an insulation sleeve 216 to electrically isolate the busbar 100-2 from the busbars 100-1 and 100-3 and/or other conductive components.

In some examples, one or more bushings 220, spacers, or other structural elements may be arranged to support the busbars 100. For example, the bushings 220 are arranged below the middle portions 124 of the busbars 100, between the busbars 100 and a frame structure 224 of the server rack 204. The bushings 200 may be comprised of electrically insulative material. Accordingly, the bushings 200 both provide structural support for the busbars 100 and provide insulation between the busbars 100 and the server rack 204.

Another example arrangement of busbars 240 is shown. In this example, one of the busbars 240 (e.g., a middle busbar) has a different shape/configuration than others of the busbars 240. More specifically, to meet clearance requirements, the middle busbar is longer than the others of the busbars 240. Accordingly, the arrangement of the busbars 240 requires busbars having different shapes/configurations, manufacturing processes/steps, etc.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process. The controller, in some implementations, may be a part of or coupled to a computer that is integrated with the system, coupled to the system, otherwise networked to the system, or a combination thereof. For example, the controller may be in the “cloud” or all or a part of a host computer system.

What is claimed is:

1. A busbar for a three-phase circuit breaker, the busbar comprising:
a first connection side including a first bend, a second bend, and a third bend, the first connection side extending in a first direction;
a second connection side including a fourth bend, the second connection side extending in the first direction; and
a middle portion extending in a second direction, perpendicular to the first direction, between the first connection side and the second connection side,
wherein the first connection side includes at least first and second layers.

2. The busbar of claim 1, wherein the first bend is approximately 90 degrees and the second and third bends are approximately 180 degrees.

3. The busbar of claim 1, wherein the fourth bend is approximately 90 degrees.

4. The busbar of claim 1, wherein the middle portion extends from a midpoint of the first connection side toward the second connection side.

5. The busbar of claim 1, wherein the at least one of the first connection side, the second connection side, and the middle portion has a rectangular cross-section.

6. The busbar of claim 1, wherein the first connection side includes one or more breaker connection points and the second connection side includes one or more conductor connection points.

7. The busbar of claim 6, wherein the one or more breaker connection points and the one or more conductor connection points include respective holes or openings.

8. The busbar of claim 6, wherein respective distances of the one or more breaker connection points from a midpoint of the first connection side are approximately equal.

9. The busbar of claim 1, wherein respective thicknesses of the first layer and the second layer are approximately equal.

10. The busbar of claim 9, wherein a thickness of the first connection side is approximately double respective thicknesses of the second connection side and the middle portion.

11. The busbar of claim 1, wherein:
the middle portion extends from a midpoint of the first connection side toward the second connection side;
the first connection side has a first end and extends from the first end away from the middle portion and toward the first bend to define the first layer;
the first connection side extends from the first bend toward the second bend to define the second layer; and
the first connection side extends from the second bend toward the first end and the middle portion to define a third layer.

12. The busbar of claim 10, wherein the first layer and the third layer are coplanar.

13. A system, comprising:
a three-phase circuit breaker; and
a plurality of the busbars claim 1, wherein each of the plurality of busbars is coupled to a respective phase of the three-phase circuit breaker.

14. A system comprising a plurality of the busbars of claim 1, wherein one of the plurality of busbars is inverted relative to others of the plurality of busbars, and wherein each of the plurality of busbars is coupled to a respective phase of the three-phase circuit breaker.

15. The system of claim 14, wherein the one of the plurality of busbars that is inverted is a middle busbar of the plurality of busbars.

16. The system of claim 14, wherein the system is a server rack.

17. The system of 16, further comprising a power distribution unit (PDU), wherein the PDU is configured to receive electrical power via the three-phase circuit breaker and the plurality of busbars.

18. The system of claim 17, further comprising at least one phase barrier arranged between adjacent busbars of the plurality of busbars.
